(19) United States
(12) Patent Application Publication
(10) Pub. No.: US 2025/0370184 A1
(43) Pub. Date: Dec. 4, 2025

(54) ON-CHIP OPTICAL THROUGH-SILICON VIA

(71) Applicant: INTERNATIONAL BUSINESS MACHINES CORPORATION, ARMONK, NY (US)

(72) Inventors: Hsianghan Hsu, Latham, NY (US); Qianwen Chen, Chappaqua, NY (US); Neng Liu, Albany, NY (US); John Knickerbocker, Monroe, NY (US)

(21) Appl. No.: 18/677,809

(22) Filed: May 29, 2024

(51) Int. Cl. G02B 6/12; G02B 6/136; G02B 6/293; H01L 25/065; H01L 25/18; H10B 80/00

(52) U.S. Cl. CPC G02B 6/12007; G02B 6/136; H01L 25/0652; H01L 25/18; H10B 80/00; G02B 6/29338

(57) ABSTRACT

A semiconductor optical waveguide is provided. The semiconductor optical waveguide has a semiconductor substrate. The semiconductor substrate defines opposing top and bottom surfaces, and an optical TSV extending substantially perpendicular to the top and bottom surfaces. The semiconductor waveguide further includes a waveguide optical circuit on the semiconductor substrate and optically connected to the optical TSV.

### BACKGROUND

### Technical Field

The present disclosure generally relates to computerized communication systems, and more particularly, to co-packaged optics integrated circuit chips.

### Description of the Related Art

Commercial datacenters and systems are competing to handle more and more data at ever increasing speeds, while holding the line on costs. Recent advancements in meeting these demands have added optical integrated circuits to electronic integrated circuits within the same packaged computer chip. This can integrate a wide variety of photonic functions into the programmed logic executed by electronic integrated circuitry, all in a co-packaged optics (CPO) integrated computer chip. CPO chips can be fabricated using silicon oxide (SiO₂) or indium phosphide and the like.

### SUMMARY

According to an embodiment, a co-packaged optics (CPO) integrated circuit chip is provided having a semiconductor substrate. The semiconductor substrate defines opposing top and bottom surfaces, and an optical through-substrate via (optical TSV) extending substantially perpendicular to the top and bottom surfaces. The CPO integrated circuit chip includes a waveguide optical circuit on the semiconductor substrate and optically connected to the optical TSV. The CPO integrated circuit chip further includes a computer processor based electronic circuit on the semiconductor substrate.

In one embodiment, a method of making a semiconductor optical waveguide is provided. The method includes etching a mold wafer to form a waveguide cavity feature and etching a substrate wafer to form an optical TSV feature. A waveguide layer is deposited on the waveguide cavity feature in the mold wafer. The mold wafer is polished to form a waveguide feature. The mold wafer is then bonded to the substrate wafer to optically connect the waveguide feature in the mold wafer to the optical TSV feature in the substrate wafer. The mold wafer is then released from the waveguide feature.

According to one embodiment, a semiconductor optical waveguide is provided. The semiconductor optical waveguide has a semiconductor substrate. The semiconductor substrate defines opposing top and bottom surfaces, and an optical TSV extending substantially perpendicular to the top and bottom surfaces. The semiconductor waveguide further includes a waveguide optical circuit on the semiconductor substrate and optically connected to the optical TSV.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 schematically illustrates a co-packaged optics (CPO) integrated circuit chip, consistent with illustrative embodiments.

FIG. 2 depicts a portion of the CPO integrated circuit chip in FIG. 1, consistent with illustrative embodiments.

FIG. 3 depicts a partial cross-sectional view of an optical TSV in the CPO integrated chip of FIG. 2, consistent with illustrative embodiments.

FIG. 4 depicts an isometric view of an optical TSV connected to four horizontal waveguides forming an optical ring resonator, consistent with illustrative embodiments.

FIG. 5 is an enlarged cross-sectional view of the optical TSV in the optical ring resonator in FIG. 4, consistent with illustrative embodiments.

FIG. 6 is similar to FIG. 4 but depicting another optical ring resonator with an alternative arrangement of the four horizontal waveguides, consistent with illustrative embodiments.

FIG. 7 is a flowchart depicting steps in a method of making a semiconductor optical waveguide, consistent with illustrative embodiments.

FIG. 8a is an elevational depiction of etching a mold wafer to form a waveguide cavity feature and etching a substrate wafer to form an optical TSV, consistent with illustrative embodiments.

FIG. 8b is an elevational depiction of depositing a waveguide layer on the mold wafer of FIG. 8a, consistent with illustrative embodiments.

FIG. 8c is an elevational depiction of polishing the waveguide layer in FIG. 8b to produce horizontal waveguide features, consistent with illustrative embodiments.

FIG. 8d is an elevational depiction of bonding the mold wafer of FIG. 8c to a top side of the substrate wafer of FIG. 8a to optically connect the top horizontal waveguide features to the optical TSV feature in the substrate wafer, consistent with illustrative embodiments.

FIG. 8e is an elevational depiction of thinning the substrate wafer in FIG. 8d, consistent with illustrative embodiments.

FIG. 8f is an elevational depiction of bonding the mold wafer of FIG. 8c to a bottom side of the substrate wafer to optically connect the bottom horizontal waveguide features to the optical TSV feature in the substrate wafer, consistent with illustrative embodiments.

FIG. 8g is an elevational depiction of releasing the mold wafer from the substrate wafer, consistent with illustrative embodiments.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

Although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It is to be understood that other embodiments can be used, and structural or logical changes can be made without departing from the spirit and scope defined by the claims. The description of the embodiments is not limiting. In particular, elements of the embodiments described hereinafter may be combined with elements of different embodiments.

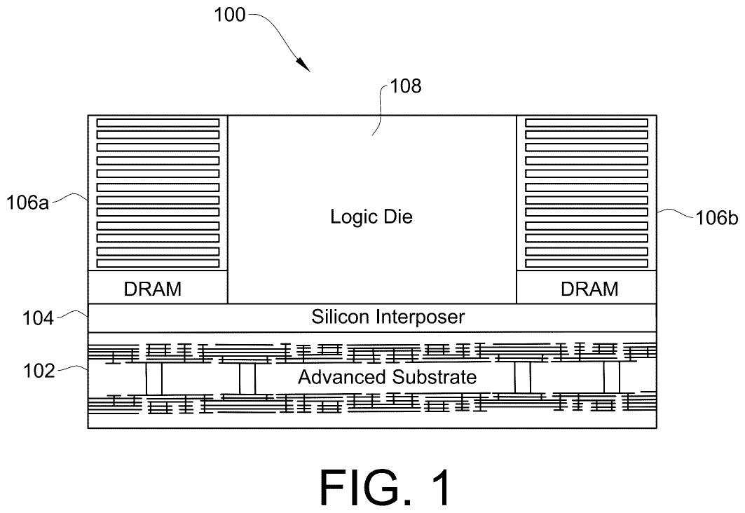

FIG. 1 illustrates a co-packaged optics (CPO) integrated circuit chip 100, consistent with illustrative embodiments. It can include a semiconductor substrate 102 with advanced electronic circuitries embedded therein. A silicon-based interposer 104 can be connected to the semiconductor substrate 102, such as by landing pad and micro-bump electrical connections. Individual memory chips, such as dynamic random-access memory (DRAM), can be stacked in non-volatile memory arrays 106. A logic die 108 can assume top level control of programmed logic and can provide volatile memory resources for doing so such as static random-access memory (SRAM).

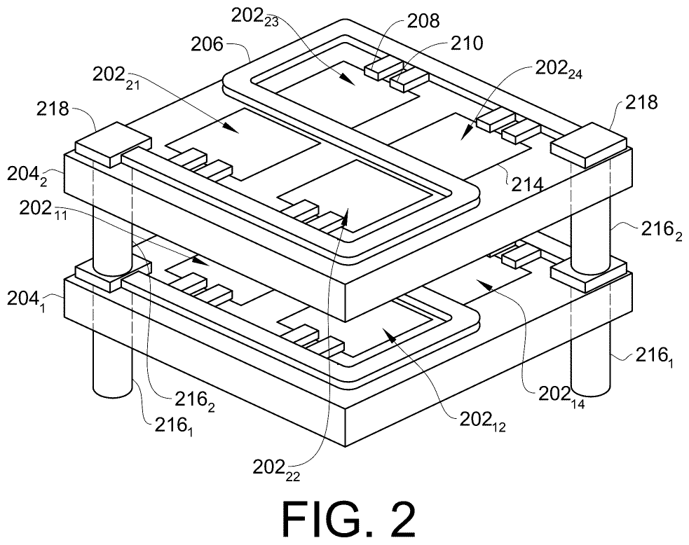

FIG. 2 depicts just one small portion of the CPO integrated circuit (IC) chip 100 in FIG. 1 that includes optical engines 202. The packaging substrate 204 in each layer can be a high-density organic substrate. This portion of the CPO IC chip 100 can be constructed as a monolithic IC chip or multiple IC chips functioning as a single IC chip. The optical engines 202 are configured for receiving, processing, and transmitting optical signals. In this example, each optical engine 202 can communicate with a horizontal optical waveguide 206 that supplies optical signals to an optical modulator 208 and a photo-detector 210. Digital and analog electronic circuitry 212 is configured to perform the necessary optical signal processing under control of processor programming instructions. A vertical optical waveguide 216 can transmit optical signals to and between different layers by employing an optical TSV, consistent with illustrative embodiments. Optical couplers 218 can optically connect a vertical optical waveguide 216 to a horizontal waveguide 206 in a layer.

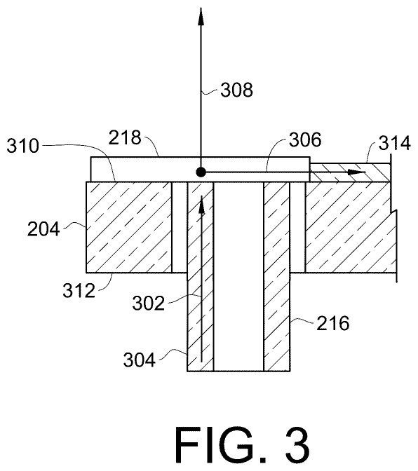

FIG. 3 is a partial cross-sectional depiction of one layer's vertical optical waveguide 216. It more particularly depicts an optical signal 302 being transmitted through an optical TSV 304 to the optical coupler 218. The optical coupler 218 can split the optical signal 302 into first optical signals 306 for processing by this layer and second optical signals 306 for processing by higher layers. A horizontal waveguide 314 can be optically connected to the optical coupler 218. In the example of FIG. 3, a proximal end of the optical TSV 304 extends substantially perpendicular from a top surface 310 of the packaging substrate 204. A distal end of the optical TSV 304 extends beyond a bottom surface 312 of the packaging substrate 204.

In these embodiments of FIG. 3, the optical TSV 304 is configured as a silicon post embedded in the packaging substrate 204 and extending between adjacent packaging substrates 204. The silicon post has a longitudinal height defined by a distance that it extends substantially perpendicular to the top and bottom surfaces 310, 312. The silicon post has a lateral width defined by a distance that it extends substantially parallel to the top and bottom surfaces 310, 312. For purposes of this description, the term “post” means a silicon-based device configured to transmit optical signals through a semiconductor substrate, such as the packaging substrate 204, and configured to have a lateral width that is less than a longitudinal height.

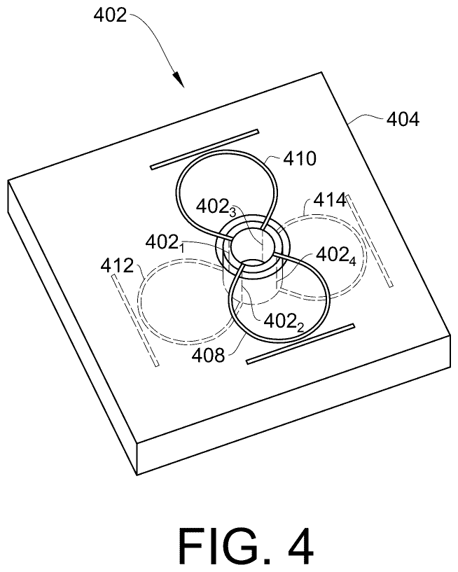

FIG. 4 depicts an isometric view of an optical TSV 402 through a portion of a semiconductor substrate 404, such as but not limited to the packaging substrate 204 in FIG. 3. In this example, the optical TSV 402 is part of an optical ring resonator 406 constructed in two different layers of the CPO integrated circuit chip 100, consistent with illustrative embodiments. The optical TSV 402 can be annularly-shaped to provide multiple silicon-based posts for connecting to horizontal waveguides. In this example, the optical TSV 402 is constructed as a hollow cylinder, although the contemplated embodiments are not so limited.

In this example of FIG. 4, the ring resonator 406 can have first and second horizontal waveguides 408, 410 forming loops that are connected to the optical TSV 402 on a top side of the semiconductor substrate 404. The ring resonator 406 can also have third and fourth horizontal waveguides 412, 414 forming loops that are connected to the optical TSV 402 on a bottom side of the semiconductor substrate 404. The optical TSV 402 optically connects the first and second waveguides 408, 410 to the third and fourth waveguides 412, 414 through the semiconductor substrate 404.

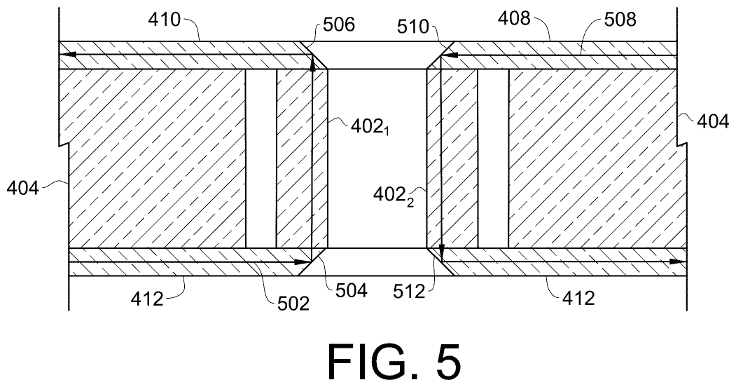

FIG. 5 is an enlarged cross-sectional depiction of the optical TSV 402 of the optical ring resonator 406 in FIG. 4, taken along a section line through the two of the optical connections via optical TSVs 402₁, 402₂. That is, FIG. 5 depicts the optical TSV 402₁ optically connecting the horizontal waveguide 412 on the bottom of the semiconductor substrate 404 to the horizontal waveguide 410 on the top of the semiconductor substrate 404. FIG. 5 also depicts the optical TSV 402₂ optically connecting the horizontal waveguide 412 on the bottom of the semiconductor substrate 404 to the horizontal waveguide 408 on the top of the semiconductor substrate 404.

As for the optical TSV 402₁, an optical signal 502 can be transmitted through the horizontal optical waveguide 412, which forms an angled reflecting surface 504 at a distal end. In an embodiment, the angled reflecting surface 504 can define a 45-degree angle, but the contemplated embodiments are not so limited. In alternative embodiments the angled reflecting surface can define angles other than 45 degrees. In this example of FIG. 5, the optical signal 502 can reflect from the angled reflecting surface 504 to be transmitted through the silicon-based post forming the optical TSV 402₁. The optical signal 502 can then impinge another angled reflecting surface 506 formed in the optical waveguide 410 on the top of the semiconductor substrate 404. The twice-reflected optical signal 502 can then be transmitted through the horizontal optical waveguide 410.

As for the optical TSV 402₂, an optical signal 508 can be transmitted through the horizontal optical waveguide 408, which forms an angled reflecting surface 510 at a distal end. In an embodiment, the angled reflecting surface 510 can define a 45-degree angle but the contemplated embodiments are not so limited. In alternative embodiments, the angled reflecting surface can define angles other than 45 degrees. In this example of FIG. 5, the optical signal 508 can reflect from the angled reflecting surface 510 to be transmitted through the silicon-based post forming the optical TSV 402₂. The optical signal 508 can then impinge another angled reflecting surface 512 formed in the horizontal optical waveguide 412 on the bottom of the semiconductor substrate 404. The twice-reflected optical signal 508 can then be transmitted through the horizontal optical waveguide 412.

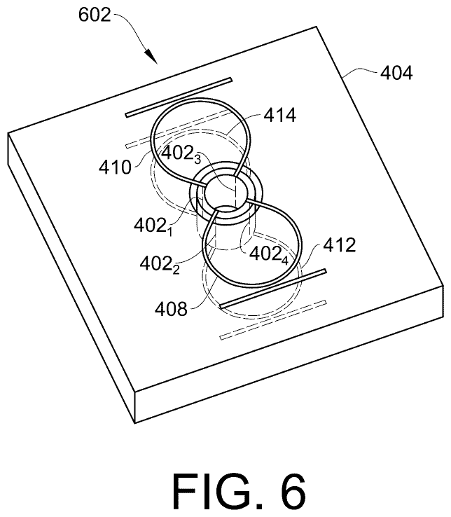

In this illustrative configuration depicted in FIG. 5, the horizontal optical waveguide 408 output is transmitted to the horizontal optical waveguide 412 input, and the horizontal optical waveguide 412 output is transmitted to the horizontal optical waveguide 410 input. The skilled artisan will understand that this configuration can provide for a single optical waveguide from the horizontal optical waveguide 408 input to the horizontal optical waveguide 410 output. This means the optical TSV 402 can advantageously route a waveguide channel, and hence an optical signal, to different layers of the CPO integrated circuit 100. The horizontal optical waveguides interconnecting the optical TSVs 402 can be unitarily formed as described below, or they can be heterogeneously formed and joined together such as, but not limited to, by optical switches, optical couplers, and the like. FIG. 6 is similar to FIG. 4 but depicting another optical ring resonator 602 with an alternative arrangement of the four horizontal waveguides 408, 410, 412, 414, consistent with illustrative embodiments.

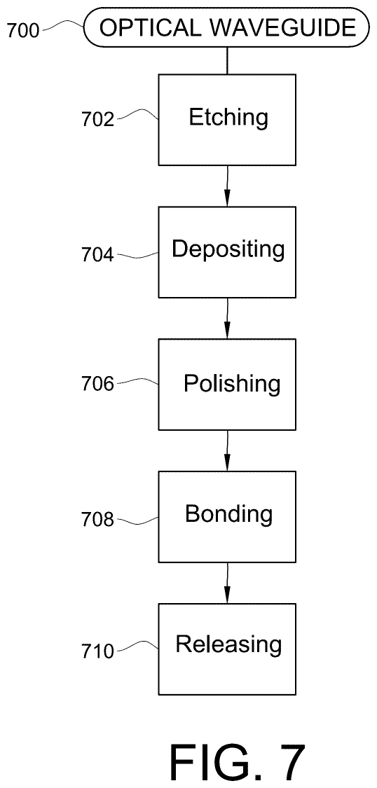

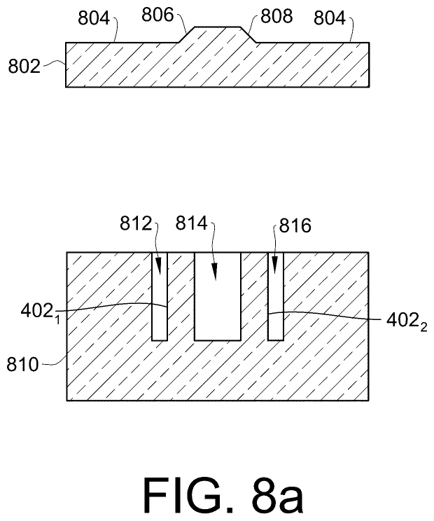

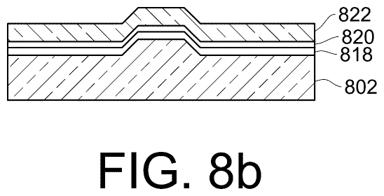

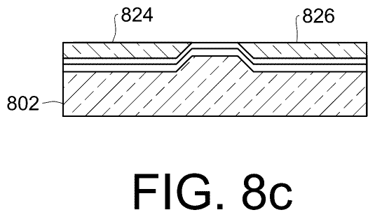

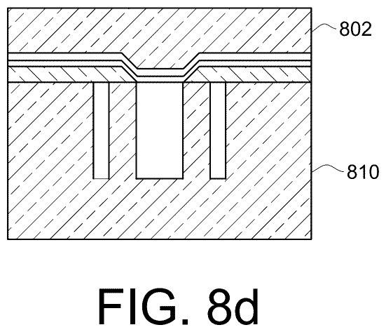

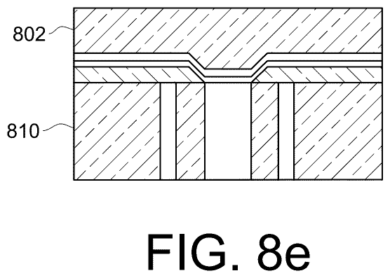

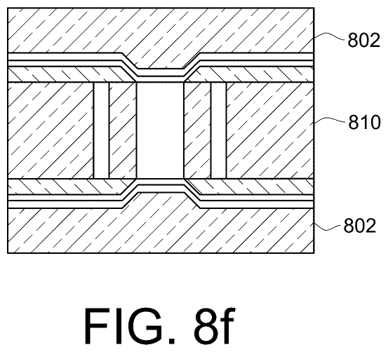

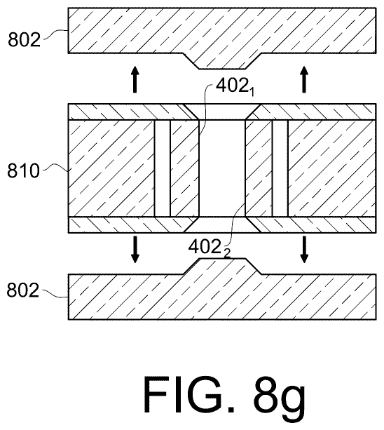

FIG. 7 is a flowchart depicting steps in a method 700 of making a semiconductor optical waveguide, consistent with illustrative embodiments. The method 700 can begin with block 702 etching a mold wafer to form a waveguide cavity feature and etching a substrate wafer to form an optical TSV, consistent with illustrative embodiments. For example, FIG. 8a depicts etching a mold wafer 802 to form two waveguide cavities 804. The etching can include etching two angled surfaces, such as 45-degree surfaces 806, 808. These angled surfaces 806, 808 can correspond to angled reflecting surfaces, such as the angled reflecting surfaces 504, 506, 510, 512 in FIG. 5. FIG. 8a also depicts etching an annular optical TSV 402 in a substrate wafer 810. This annular configuration of the optical TSV 402 provides two silicon-based posts along this depicted cross-sectional plane. A horizontal waveguide can be optically connected to each of the two optical TSVs 402₁, 402₂ in this arrangement.

In this detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the drawing figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip. As used herein, the term “vertical” describes an orientation that is arranged perpendicular to the first surface of a chip, chip carrier, or semiconductor body. As used herein, the terms “coupled” and/or “optically coupled” are not meant to mean that the elements must be directly coupled together—intervening elements may be provided between the “coupled” or “optically coupled” elements. In contrast, if an element is referred to as being “directly connected” or “directly coupled” to another element, there are no intervening elements present. The meaning of elements being “optically connected” refers to a low-dispersion transmission of photonic power between the elements.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments can be used and structural or logical changes can be made without departing from the spirit and scope defined by the claims. The description of the embodiments is not limiting. In particular, elements of the embodiments described hereinafter may be combined with elements of different embodiments.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Fabrication of semiconductor devices can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, the optical TSVs 402 can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

The mold wafer 802 and the substrate wafer 810 can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

In some embodiments of the disclosure, the mold wafer 802 and the substrate wafer 810 can include a buried oxide layer in a silicon-on-insulator (SOI) configuration. The buried oxide layer can be made of any suitable dielectric material, such as, for example, a silicon oxide. In some embodiments of the invention, the buried oxide layer can be formed to a thickness of about 10-200 nm, although other thicknesses are within the contemplated scope of the disclosure. In some embodiments, the semiconductor structure can also be formed without the buried oxide layer. In that case, a shallow trench isolation (STI) can be formed to isolate device from device.

The mold wafter 802 and the substrate wafer 810 can begin as a semiconductor wafer manufactured in a foundry. These wafers can be processed by front-end-of-line (FEOL) processes to fabricate an array of IC dies. Each IC die can have integrated circuitry that includes semiconductor devices, such as the optical TSVs 402. An array of rows and columns of IC dies on the semiconductor wafer can range in numbers from tens to tens of thousands of individual IC dies. Round wafers typically have diameters within a range of about 100 millimeters (“mm”) to 300 mm. The number depends on many factors, namely the individual IC die size and the wafer size. Scribe-line channels can be created between adjacent rows and columns, which are free of semiconductor devices but can contain non-electronic semiconductor devices such as the optical TSVs 402.

The wafer material can be any suitable semiconductor material that a skilled artisan recognizes to be suitable for forming ICs that include optical TSVs 402. For example, wafers can be composed of a monocrystalline silicon-containing material, such as bulk or SOI single crystal silicon. The semiconductor material can be doped with an impurity to alter its optical and electrical properties. For instance, the wafer can be doped with an n-type impurity to render it initially n-type or doped with a p-type impurity to render it initially p-type.

Dielectric layers (not depicted) can be formed on the wafers such as by lithographic and etching techniques. Etch stop layers (not depicted) can be applied on dielectric layers such as by conventional deposition techniques. The etch stop layers cap the underlying dielectric layers and can be formed from any material that etches selectively to the dielectric material. Typical materials can be a thin film of silicon nitride, silicon carbonitride, silicon oxycarbonitride, or silicon carbide deposited by, for example, plasma enhanced chemical vapor deposition.

The dielectric layers can be any suitable organic or inorganic dielectric material such as, but not limited to, silicon dioxide, fluorine-doped silicon glass, and combinations of these dielectric materials. Alternatively, the dielectric layers can be characterized by a relative permittivity or dielectric constant smaller than the dielectric constant of silicon dioxide, which is about 3.9. Candidate low-k dielectric materials for the dielectric layers include, but are not limited to, porous and nonporous spun-on organic low-k dielectrics, such as spun-on aromatic thermoset polymer resins like polyarylenes, porous and nonporous inorganic low-k dielectrics, such as organosilicate glasses, hydrogen-enriched silicon oxycarbide, carbon-doped oxides, and combinations of these and other organic and inorganic dielectrics. If the dielectric layers are composed of a low-k dielectric material, the physical and material properties of the etch stop layers can be adjusted to operate as a barrier film that optimizes resist poisoning characteristics. Dielectric layers can be deposited by any number of well-known conventional techniques such as sputtering, spin-on application, chemical vapor deposition (“CVD”) process or a plasma enhanced chemical vapor deposition process (“PECVD”).

Resist layers can include a radiation-sensitive organic material applied as a thin film to dielectric layers, such as by spin coating. Resist layers can be pre-baked, exposed to radiation to impart a latent image of a via pattern, baked, and then developed with a chemical developer. The chemical developer removes nonpolymerized material to transform the latent image of the optical TSV pattern in a resist layer into a final image pattern. The final image pattern imparted in the resist layer includes openings exposing the dielectric layer beneath. Procedures for applying and lithographically patterning a resist layer using a photomask and lithography tool are known to the skilled artisan. Alternatively, a hardmask (not depicted) can be applied to the dielectric layer before the resist layer. In subsequent patterning steps, the hardmask is etched in conjunction with the resist layer, which is removed after patterning the hardmask. The hardmask then serves as the primary mask for the etching process.

FIG. 8a depicts the optical TSVs 4021, 4022 are created by etching trenches 812, 814, 816 that extend to the etch stop layer. The portion of a dielectric layer not masked by a resist layer is removed with an etching process, such as reactive ion etching (“RIE”), which is capable of producing substantially vertical sidewalls for the etched-away openings. After penetrating through the dielectric layer, the etch stop layer halts the vertical progress of the etching process so that the underlying silicone and metallization in lower dielectric layers is not etched. After etching the trenches 812, 814, 816, the residual resist layer can be removed such as with a wet chemical stripper or a dry oxidation-based photoresist removal technique, like plasma ashing with an oxygen plasma.

An adhesion promoter, such as hexamethyldisilazane, can be initially applied on the dielectric layer to promote adhesion of the resist layer. A spin coating process can entail placing the wafer on a spin coater, dispensing the liquid resist solution onto the top surface of the dielectric layer, and operating the spin coater to rapidly spin the wafer. Spinning disperses the liquid resist solution supplied to the center of the wafer radially outward by centrifugal forces to coat the entire top surface and to provide the resist layer with a nominally uniform thickness throughout. A typical spin coating process runs at a speed range of about 1,000 to 5,000 revolutions per minute (“rpm”) for about one minute or less and results in a physical layer thickness between about 0.5 microns and about 2.5 microns. The resist layer can then be heated in a soft baking or pre-baking process to drive off excess solvent and to promote partial solidification.

The soft-baked resist layer can then be exposed to a pattern of radiation to impart a latent image of a trench pattern. For optical lithography, the pattern of radiation can be generated using a photomask and an optical stepper of a lithography tool and then imaged onto the resist layer. Regions of the resist layer exposed to the radiation become chemically less stable. Regions of the resist layer that are not exposed to the radiation remain chemically stable. This chemical modification of the exposed regions of the resist layer permits subsequent removal by contact with a chemical developer.

The resist layer can be subjected to a post-exposure bake process before the developing process. The elevated temperature of the post-exposure bake process drives photoproduct diffusion in the resist layer, minimizes the negative effects of standing waves in the resist layer, and drives acid-catalyzed reactions in chemically amplified positive resists. The resist layer can then develop with the use of a developer to transform the latent image into a final image pattern with the openings and waveguide cavity feature to be etched. Portions of the dielectric layer not masked by the resist layer are exposed to a developer, such as can be delivered on a spin coater in a manner similar to the delivery of the resist solution. An exemplary developer that can be used to develop positive photoresist is an alkali developing liquid, such as tetramethylammonium hydroxide, itself or in solution with a surfactant. The resulting resist layer can then be subjected to a hard-baking process, which solidifies the residual photoresist of the patterned resist layer 424 to increase durability and robustness.

Returning to FIG. 7, the method 700 can continue with block 704 depositing a waveguide layer on the mold wafer 802 in FIG. 8a, consistent with illustrative embodiments. For example, FIG. 8b depicts depositing an anti-reflective coating 818 on the mold wafer 802, then depositing a release layer 820 on the anti-reflective coating layer 818, and then depositing a waveguide layer 822 on the release layer 820. Block 706 in the method 700 of FIG. 7 can then polish the waveguide layer 822 in FIG. 8b to produce horizontal waveguide features, consistent with illustrative embodiments. FIG. 8c depicts illustrative waveguide features 824, 826 from polishing the waveguide layer 822 in FIG. 8b. Block 708 in the method 700 of FIG. 7 can then bond the mold wafer 802 in FIG. 8c to the substrate wafer 810 in FIG. 8a. FIG. 8d is an elevational depiction illustrating a bonding of the mold wafer 802 of FIG. 8c to a top side of the substrate wafer 810 of FIG. 8a. This bonding can be achieved by fusion bonding, although the contemplated embodiments are not so limited.

FIG. 8e depicts thinning the substrate wafer 810 by further etching. FIG. 8f depicts bonding another mold wafer 802 to the bottom of the substrate wafter 810. The second mold wafer 802 can be layered and bonded twice to the substrate wafer 810, or two mold wafers 802 can be individually layered and bonded to the substrate wafer 810. In either event, block 710 in the method 700 of FIG. 7 can then release the mold wafer(s) 802. FIG. 8g depicts such a release, after having formed the optical TSVs 4021, 4022 that are disclosed in FIG. 5 and the descriptions thereof.

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings. The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain. Numerous other embodiments are also contemplated. These include embodiments that have fewer, additional, and/or different components, steps, features, objects, benefits, and advantages. These also include embodiments in which the components and/or steps are arranged and/or ordered differently.

Aspects of the present disclosure are described herein with reference to illustrations and/or block diagrams of a method, apparatus (systems), and computer program products according to embodiments of the present disclosure. It will be understood that each step of the flowchart illustrations and/or block diagrams, and combinations of blocks in the call flow illustrations and/or block diagrams, can be implemented by computer readable program instructions.

These computer readable program instructions may be provided to a processor of a computer, special purpose computer, or other programmable data processing apparatus to produce a machine, such that the instructions, which execute via the processor of the computer or other programmable data processing apparatus, create means for implementing the functions/acts specified in the call flow process and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the call flow and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the call flow process and/or block diagram block or blocks.

The flowchart and block diagrams in the Figures illustrate the architecture, functionality, and operation of possible implementations of systems, methods, and computer program products according to various embodiments of the present disclosure. In this regard, each block in the call flow process or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or call flow illustration, and combinations of blocks in the block diagrams and/or call flow illustration, can be implemented by special purpose hardware-based systems that perform the specified functions or acts or carry out combinations of special purpose hardware and computer instructions.

While the foregoing has been described in conjunction with exemplary embodiments, it is understood that terms such as “exemplary” and “illustrative” are merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed:

1. A co-packaged optics (CPO) integrated circuit chip, comprising:
a semiconductor substrate, defining:
opposing top and bottom surfaces; and
an optical through-substrate via (optical TSV) extending substantially perpendicular to the top and bottom surfaces;
a waveguide optical circuit on the semiconductor substrate and optically connected to the optical TSV; and
a computer processor based electronic circuit on the semiconductor substrate.

2. The CPO integrated circuit chip of claim 1, wherein the optical TSV comprises a silicon-based post.

3. The CPO integrated circuit chip of claim 1, wherein the optical TSV comprises:
a longitudinal height defined by a distance that the optical TSV extends substantially perpendicular to the top and bottom surfaces; and
a lateral width defined by a distance that the optical TSV extends substantially parallel to the top and bottom surfaces,
wherein the lateral width is less than the longitudinal height.

4. The CPO integrated circuit chip of claim 1, wherein the waveguide optical circuit comprises:
a first optical waveguide on the semiconductor substrate and optically connected to the optical TSV; and
a second optical waveguide on the semiconductor substrate and optically connected to the optical TSV,
wherein the optical TSV optically connects the first and second optical waveguides together.

5. The CPO integrated circuit chip of claim 4, further comprising:
a third optical waveguide on the semiconductor substrate and optically connected to the optical TSV; and
a fourth optical waveguide on the semiconductor substrate and optically connected to the optical TSV,
wherein the optical TSV optically connects the third and fourth optical waveguides together.

6. The CPO integrated circuit chip of claim 4, wherein the first and second optical waveguides are on opposing sides of the semiconductor substrate.

7. The CPO integrated circuit chip of claim 4, wherein at least one of the first and second optical waveguides defines a loop in an optical ring resonator device.

8. The CPO integrated circuit chip of claim 4, wherein at least one of the first and second optical waveguides forms a reflecting surface in optical communication with the optical TSV.

9. The CPO integrated circuit chip of claim 5, wherein:
at least one of the first and second optical waveguides defines a loop in an optical ring resonator device above the semiconductor substrate; and
at least one of the third and fourth optical waveguides defines a loop in the optical ring resonator device below the semiconductor substrate.

10. The CPO integrated circuit chip of claim 1, wherein the optical TSV defines an annularly-shaped cross section.

11. A method of making a semiconductor optical waveguide, comprising:
etching a mold wafer to form a waveguide cavity feature;
etching a substrate wafer to form an optical through-substrate via (optical TSV) feature;
depositing a waveguide layer on the waveguide cavity feature in the mold wafer;
polishing the mold wafer to form a waveguide feature;
bonding the mold wafer to the substrate wafer to optically connect the waveguide feature in the mold wafer to the optical TSV feature in the substrate wafer; and
releasing the mold wafer from the waveguide feature.

12. The method of claim 11, further comprising:
depositing a second waveguide layer on the waveguide cavity feature in the mold wafer;
polishing the mold wafer to form a second waveguide feature;
bonding the mold wafer to the substrate wafer to optically connect the second waveguide feature in the mold wafer to the optical TSV in the substrate wafer; and
releasing the mold wafer from the waveguide feature.

13. The method of claim 11, further comprising:
depositing a second waveguide layer on a waveguide cavity feature in a second mold wafer;
polishing the second mold wafer to form a second waveguide feature;
bonding the second mold wafer to the substrate wafer to optically connect the second waveguide feature in the second mold wafer to the optical TSV in the substrate wafer; and
releasing the second mold wafer from the waveguide feature.

14. The method of claim 11, wherein etching the mold wafer comprises etching a 45-degree surface in the waveguide cavity feature corresponding to an angled reflecting surface in the waveguide feature.

15. The method of claim 11, further comprising depositing an anti-reflective coating layer between the mold wafer and the waveguide layer.

16. The method of claim 11, wherein the bonding comprises fusion bonding the mold wafer to the substrate wafer.

17. A semiconductor optical waveguide, comprising:
a semiconductor substrate, defining:
opposing top and bottom surfaces; and
an optical through-substrate via (optical TSV) extending substantially perpendicular to the top and bottom surfaces; and
a waveguide optical circuit on the semiconductor substrate and optically connected to the optical TSV.

18. The semiconductor optical waveguide of claim 17, the optical TSV comprising:
a silicon-based annular post, wherein:
a longitudinal height of the silicon-based annular post is defined by a distance that the optical TSV extends substantially perpendicular to the top and bottom surfaces; and
a lateral width of the silicon-based annular post is defined by a distance that the optical TSV extends substantially parallel to the top and bottom surfaces, and
wherein the longitudinal height of the silicon-based annular post is greater than the lateral width of the silicon-based annular post.

19. The semiconductor optical waveguide of claim 17, wherein the waveguide optical circuit comprises:
a first optical waveguide on a first side of the semiconductor substrate and optically connected to the optical TSV; and
a second optical waveguide on an opposing second side semiconductor substrate and optically connected to the optical TSV,
wherein the optical TSV optically connects the first and second optical waveguides together.

20. The semiconductor optical waveguide of claim 19, further comprising:
a third optical waveguide on the first side of the semiconductor substrate and optically connected to the optical TSV; and
a fourth optical waveguide on the opposing second side of the semiconductor substrate and optically connected to the optical TSV,
wherein the silicon post optically connects the third and fourth optical waveguides together.
